(19) United States
(12) Patent Application Publication
(10) Pub. No.: US 2001/0003381 A1
(43) Pub. Date: Jun. 14, 2001

(54) METHOD TO LOCATE PARTICLES OF A PREDETERMINED SPECIES WITHIN A SOLID AND RESULTING STRUCTURES

(76) Inventors: MARIUS ORLOWSKI, AUSTIN, TX (US); OLUBUNMI OLUFEMI ADETUTU, AUSTIN, TX (US); PHILIP TOBIN, AUSTIN, TX (US); BICH YEN NGUYEN, AUSTIN, TX (US); HSING HUANG TSENG, AUSTIN, TX (US)

Correspondence Address: PATRICIA GODDARD, MOTOROLA, INC., AUSTIN INTELLECTUAL PROPERTY LAW SECTION, MD: TX 32/PL02, 7700 WEST PARMER LANE, AUSTIN, TX, 78729, US

(21) Appl. No.: 09/082,129

(22) Filed: May 20, 1998

(51) Int. Cl. H01L 23/29

(52) U.S. Cl. 257/787; 257/790

(57) ABSTRACT

The present invention relates to a method to locate particles of a predetermined species within a solid, more specifically to form an oxy-nitride dielectric for VLSI applications. A layer (18) of a substance (YZ) is formed upon a solid (10) and a chemical reaction is performed between the substance (YZ) and a gas (X), thereby releasing particles (Z) of a predetermined species which incorporate into the solid (10). This method is used, for example, to form an oxy-nitride dielectric by incorporating nitrogen within a silicon oxide layer (28′).

### FIELD OF THE INVENTION

The present invention relates to methods to locate particles of a predetermined species within-a solid, more specifically to form an oxy-nitride dielectric with specific properties and oxides and silicides doped with metals for VLSI applications.

### BACKGROUND OF THE INVENTION

Advanced silicon technologies require low thermal budget processing of high quality dielectric layers. As the gate oxide thickness reduction continues below 100 Å, these thin oxide layers are subject to stringent requirements of uniformity, hot carrier resistance, radiation hardness and resistance against boron and phosphorus penetration usually from polysilicon gates. These requirements cannot be met by a pure silicon oxide layer. It is well known that the incorporation of nitrogen near the substrate Si/SiO₂ interface and SiO₂/poly-Si interface improves the oxide properties to meet the above requirements. Ion location of nitrogen into silicon substrate followed by an oxidation process has also been reported in the literature (C. T. Liu et al. IEDM 1996, pp. 499). This process has been shown to produce very precise nitrogen control. It however suffers from low throughput.

Oxide nitride oxide (ONO) structures which provide isolating layers in capacitances, where silicon nitride is used to raise the dielectric constant, are well known in the art. Such structures have been generated by chemical vapor deposition (CVD). The quality of the ONO interface surface is not sufficient, so that prior art layers have to be much thicker than necessary with respect to the needs of capacitances.

Present methods of doping a semiconductor layer use thick layers as source which provide the dopant. Dopant atoms diffuse from the thick layer source into the underlayer, then the source layer or what is left of it is removed by etching.

Present methods of nitridation of oxide are furnace-based methods employing N₂O and NO oxidation at high temperatures typically between 850° C. and 1100° C. In these methods wafers are exposed to a gaseous ambient with nitrogen content. In addition, N₂ location has been used for introducing nitrogen (R. Kraft et. al., JEST, B, 15 (4), pp. 967). These methods succeed in incorporating the nitrogen only at the substrate Si/SiO₂ interface and are non-scaleable with decreasing oxide thickness to 15 Å.

Therefore, a need continues to exist for improved methods and structures for forming dielectric layers on or between semiconductor regions, that overcome these and other limitations of the prior art.

### BRIEF DESCRIPTION OF THE DRAWINGS

FIG. 1 is a schematic diagram of a cross section of a stack of layers showing reaction types employed in the present invention;

FIG. 2 is a schematic diagram of a cross section of a stack of layers showing a reaction employed in another embodiment of the present invention;

FIG. 3 is a schematic diagram of a result of a measurement from two different stacks of layers after the reaction shown in FIG. 2;

FIG. 4 is a schematic diagram of a cross section of a stack of layers showing a reaction type employed in a further embodiment of the present invention;

FIG. 5 is a schematic diagram of a cross section of a stack of layers showing a reaction employed in another embodiment of the present invention;

FIG. 6 is a schematic diagram of a cross section of a stack of layers showing a reaction type employed in yet another embodiment of the present invention;

FIG. 7 is a schematic diagram of a cross section of a stack of layers showing a reaction employed in still another embodiment of the present invention;

FIG. 8 is a schematic diagram of a cross section of a stack of layers showing a reaction employed in a further embodiment of the present invention in order to generate metal doped silicide;

FIG. 9 is a schematic diagram of a cross section of a stack of layers showing a reaction employed in a still further embodiment of the present invention in order to generate nitrogen doped oxide.

### DETAILED DESCRIPTION OF THE PREFERRED EMBODIMENT

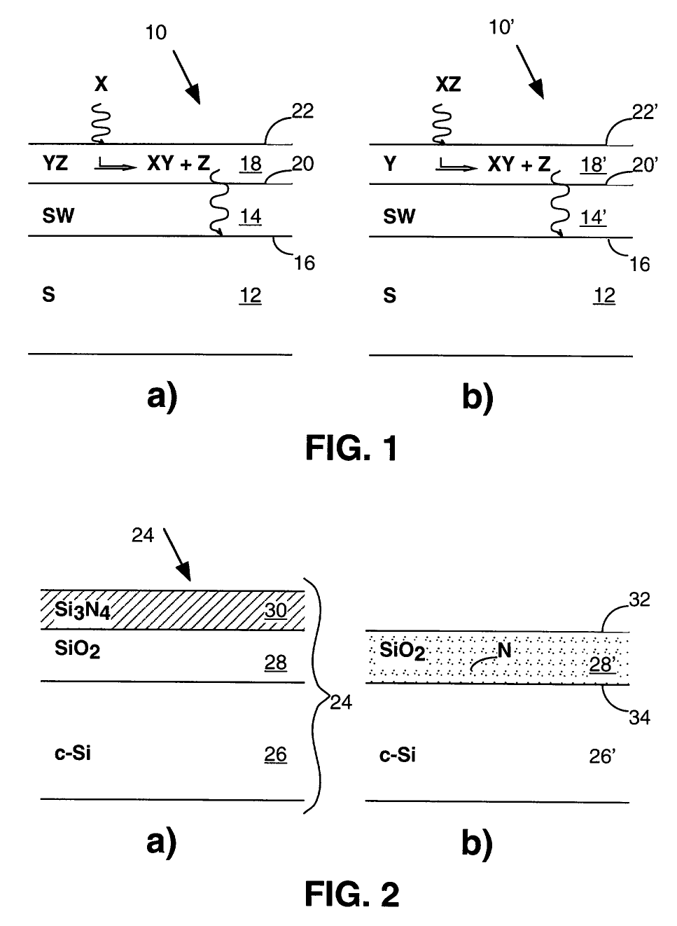

FIG. 1 shows in a schematic form, a cross section of a stack of layers at a layer—substrate interface illustrating the principal methods to locate particles of a predetermined species Z within solid 10 according to the present invention. Particles of the predetermined species are, depending on the desired resulting product and the reaction involved atoms, molecules, free-radicals or molecular ions. Solid 10 comprises substrate 12 (e.g. silicon) and layer 14 applied thereto with interface 16 therebetween. Substrate 12 consists of compound S and layer 14 consists of compound SW being built of subcompound S and subcompound W.

In FIG. 1a), layer 18 of compound YZ has been formed onto layer 14 with border 20 therebetween. Again, compound YZ is built of subcompound Y and subcompound Z. Beyond surface 22 of solid 10 is a gas comprising compound X. This is the state when chemical reactions will start and incorporation of particles of a predetermined species Z within solid 10 will begin.

The method according to the present invention employs chemical reactions between different compounds under appropriate conditions. Those skilled in the art will know such compounds and conditions. Further, they will understand the expressions “compound” and “subcompound” as a general term including elements and molecular substances. As an example, compound X can be a molecule of atoms of different elements, a molecule of atoms of the same element, free-radicals or atomic or molecular ions.

A chemical reaction between compound YZ of layer 18 and compound X of the gas occurs in or on the surface of layer 18. The reaction products are a new compound XY built of subcompound X and subcompound Y, and released particles of species Z. These particles of species Z incorporate into layer 14.

In FIG. 1b), layer 18′ of compound Y has been formed onto layer 14′ with border 20′ therebetween. Now, beyond surface 22′ of solid 10′ is a gas comprising compound XZ. Again, compound XZ is built of subcompound X and subcompound Z. A chemical reaction between compound Y of layer 18′ and compound XZ of the gas occurs in or on the surface of layer 18′. Here also the reaction products are a new compound XY built of subcompound X and subcompound Y, and released particles of species Z. These particles of species Z incorporate into layer 14′.

Ordinarily in diffusion processes, the concentration of diffused particles of species Z within layer 14 will decrease from border 20 to interface 16. A portion of the particles of species Z will pass interface 16 and diffuse into substrate 12. Because of intermolecular effects in a transition range around interface 16 it is possible that particles of species Z accumulate in that transition range.

During the reaction, Z is released and it incorporates through layer SW to the SW/S interface. Desired accumulation of species Z at the SW/S interface can improve properties, as in the case of nitrided oxide. Under appropriate reaction conditions and a given thickness of layer 14 the amount of species Z at the SW/S interface depends on the thickness of layer 18. This thickness of layer 18 can be controlled very precisely. Further, as the thickness of layer 18 is defined and limited, the incorporation of particles of species Z is self-limiting. It stops, when the complete layer 18 has been consumed by the reaction. Therefore, the amount of species Z at the SW/S interface can be controlled more precisely than according to prior art.

FIG. 2 is a schematic diagram of a cross section of stack of layers 24 showing a reaction employed in another embodiment of the present invention. FIG. 2a) shows stack of layers 24 before the chemical reaction involving X, Y and Z starts. For example, layer 28 of oxide SiO₂ is formed on substrate 26 of crystalline or polycrystalline silicon by chemical vapor deposition (CVD), rapid thermal oxidation (RTO) or any other method. Thin layer 30 of nitride Si₃N₄ of predetermined thickness is deposited on layer 28 using any process for generating silicon nitride or ONO (oxide-nitride-oxide) layers. Thus, stack of layers 24 is complete.

Now, the nitride of layer 30 is reoxidized by dry oxidation, diluted steam oxidation, or RTO. In the accompanying reaction, according to FIG. 1a), X, Y and Z are oxygen O, silicon Si and nitrogen N, respectively, and S and W are silicon Si and oxygen O, respectively. The Si₃N₄ is oxidized to SiO₂. That means, each oxidized Si₃N₄ molecule releases four nitrogen atoms. A portion of these released nitrogen particles will incorporate into layer 28 relating to layer SW in FIG. 1. Other nitrogen atoms will form a gaseous reaction exhaust which is not relevant for the current invention.

FIG. 2b) shows layers 26′ and 28′ which result from layers 26 and 28 after the chemical reaction. Layer 28′ has nitrogen atoms incorporated. Former layer 30 of nitride has been consumed completely by the reaction, providing new stack surface 32 and interface 34. The reaction stops when no nitride is left for oxidation. Thus, the incorporation of nitrogen atoms is self-limiting. Further, the process for nitrogen incorporation is controllable, since thin Si₃N₄ deposition is much better controlled than prior art thermal nitridation. This results in better uniformity of incorporated nitrogen atoms across the silicon wafer and from wafer to wafer, particularly for 8 and 12 inch wafer processes. Compared to the prior art, the proposed method allows a lower temperature processing than with N₂O, which requires a temperature of about 950° C., and which is non-scaleable with decreasing oxide thickness to 15 Å.

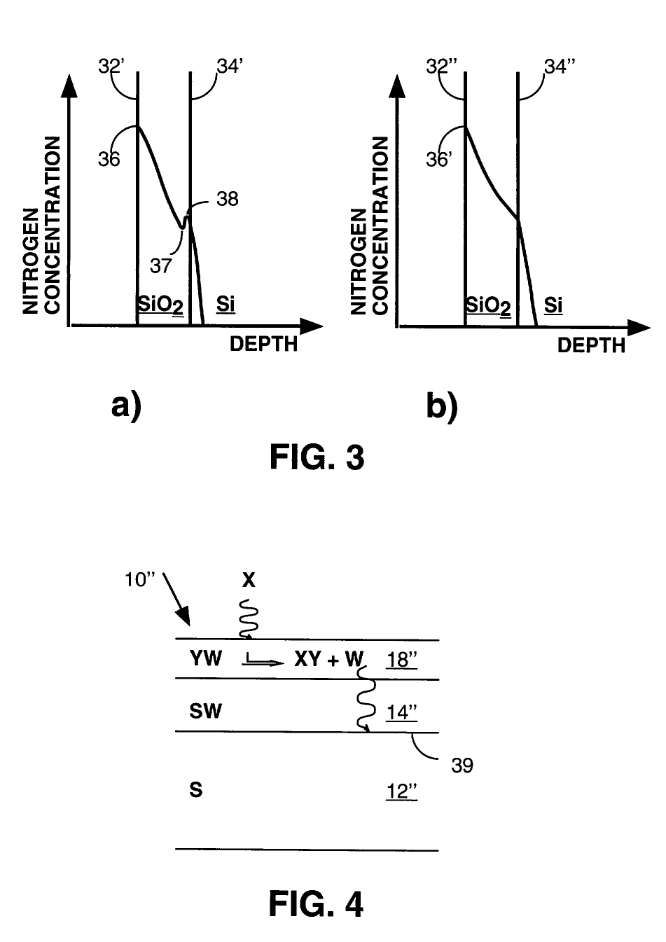

FIG. 3 is a schematic diagram of a result of an analysis from two different stacks of layers after the processing explained in FIG. 2. In a direction into the stack beginning at the outer surface the nitrogen concentration is shown as a function of depth relative to that surface. Primed reference numbers 32′, 32″ and 34′, 34″ in FIG. 3 refer to similar items 32 and 34 in FIG. 2b).

FIG. 3a) shows schematically the nitrogen distribution of a “thick” oxide of thickness of about sixty to seventy Angstrom Units (Å) (i.e. into six to seven nm). A nitrogen accumulation appears around interface 34′ such that there is an absolute maximum 36 of nitrogen concentration within the SiO₂ layer 28′ and a local maximum 38 of nitrogen concentration at or near the Si/SiO₂ interface and with a local minimum 37 in between.

FIG. 3b) shows schematically the nitrogen distribution of a “thin” oxide of thickness of less than about fifty Å. There is little or no nitrogen accumulation around interface 34″ such that within the SiO₂ layer 28′ there is only an absolute maximum 36′ of nitrogen concentration.

In the method according to the invention, the oxide layer is preferably of a thickness of the range from 1 nm to 15 nm. Further, the nitride layer is usefully of a thickness less than 10 nm and preferably of the range from 2 nm to 6 nm. The method according to the invention allows processing at temperatures less than 1100° C. The preferred range of temperatures is between 700° C. and 1100° C.

FIG. 4 is a schematic diagram of a cross section of stack of layers 10″ showing a reaction employed in a further embodiment of the present invention. FIG. 4 shows a stack of layers 10″ and process similar to that of FIG. 1a) with the important difference that Z=W, that is, instead of subcompound Z of FIG. 1a) there is now subcompound W in both layer 14″ of compound SW and layer 18″ of compound YW. When the chemical reaction in layer 18″ is running, subcompound W provides released particles of a predetermined species, now W, which incorporate through layer 14″. After passing interface 39, particles W are built into the local crystal structure, transforming it from S to SW near interface 39. Thus, layer 14″ is growing and interface 39 is translated into substrate 12″. This is a method to regrow layer SW on an atomic scale, in a controlled way. This embodiment allows a controlled regrowth of dielectric layers on a microscopic scale for sub 0.1 μm transistors with a gate oxide smaller than, for example, 30 Å (i.e. 3 nm). This is of great practical utility.

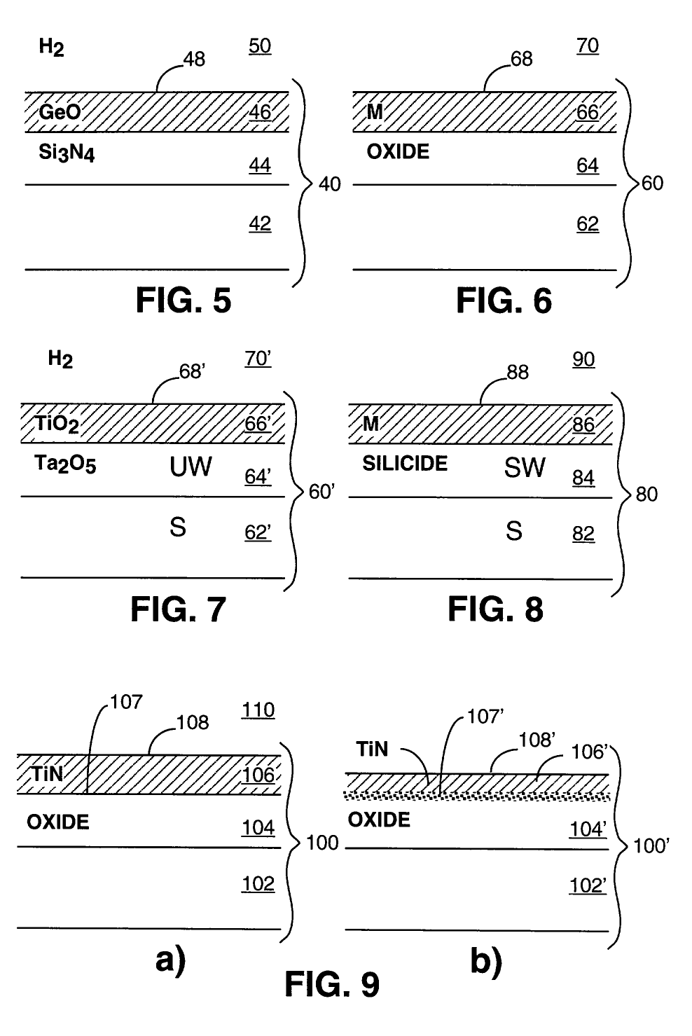

FIG. 5 is a schematic diagram of a cross section of stack of layers 40 showing a reaction employed in another embodiment of the present invention in order to generate germanium-doped Si₃N₄. Stack of layers 40 is similar to stack of layers 24 of FIG. 2a) and has substrate 42 of compound S, layer 44 of compound SW, and layer 46 of compound YZ with surface 48 towards gas 50 comprising compound X. In this embodiment, according to FIG. 5, the compounds are X=hydrogen H, Y=oxygen O, Z= germanium Ge, S=silicon Si and W=nitrogen N. Therefore, layer 44 of compound SW, is of silicon nitride Si₃N₄ and layer 46 of compound YZ is of GeO. Layer 46 can be sputtered or deposited by low temperature CVD on top of Si₃N₄ layer 44. Gas 50, for example, contains hydrogen as compound X, i.e. in molecular form H₂.

Stack of layers 40 is shown before the chemical reaction involving X, Y and Z starts. Annealing stack of layers 40 in H₂will release Ge for incorporation into Si₃N₄ layer 44 thereby raising the dielectric constant. Subsequent N₂ annealing can remove hydrogen which is usually undesirable. It is known that controlled incorporation of Ge into silicon nitride increases the dielectric constant of the Ge—Si₃N₄ compound. This is a very useful result.

FIG. 6 is a schematic diagram of a cross section of stack of layers 60 showing a reaction employed in yet another embodiment of the present invention in order to generate metal doped oxide. Stack of layers 60 is similar to stack of layers 24 of FIG. 2a) and has substrate 62 of compound S, layer 64 of, and thereupon layer 66 of compound YZ with surface 68 towards gas 70 comprising compound X. Layer 64 of compound UW is, for example, an oxide layer (SiO₂, Ta₂O₅, TiO₂). Layer 66 of compound YZ contains the desired metal M, i.e. Z=M. Note that in this embodiment, according to FIG. 6, layer 64 is of compound UW which an oxide does not include compound S of substrate 62.

The agent X in gas 70 is chosen so as to form a compound XY releasing Z which will subsequently incorporate into subjacent layer SW comprising the layer as described above. Stack of layers 60 is shown before the chemical reaction involving X, Y and Z starts. The reaction will result in very controlled doping of the layer with foreign metal particles. This is a very useful result.

FIG. 7 is a schematic diagram of a cross section of stack of layers 60′ showing an example of a preferred application where the thermodynamics and kinetics are favorable, namely the doping or controlled incorporation of titanium Ti into Ta₂O₅. It is known that introduction of Ti into thallium oxide Ta₂O₅ has the effect of increasing the dielectric constant. Introduction of Ti into Ta₂O₅ by any method is therefore of interest. This is directly applicable to a DRAM storage dielectric or a high K gate dielectric for Si MOSFETS. FIG. 7 is similar to FIG. 6 and like parts have like but primed reference numbers. Stack of layers 60′ has substrate 62′ of compound S, layer 64′ of compound SW and thereupon layer 66′ of compound YZ with surface 68′ towards gas 70′ comprising compound X. According to the invention, TiO₂ is deposited on top of a previously formed Ta₂O₅ layer preferably by reactive sputtering, compound target sputtering or CVD. Layer 64′ of compound SW is of Ta₂O₅ and layer 66′ of compound YZ is of TiO₂ with Y=O and Z=Ti. Gas 70 contains hydrogen as compound X, i.e. H₂. Substrate 62′ is, for example, silicon or other semiconductor structures. In this embodiment, according to FIG. 7, the compounds are X=H, Y=O, Z=Ti, S=Si, U=Ta and W=O.

Exposure to H₂ has the effect of reducing the TiO₂ layer thereby releasing O₂ from the top layer and liberating Ti for incorporation into the Ta₂O₅. A subsequent inert ambient anneal can release residual hydrogen from the (TiₓTa₍₁₋ₓ₎)₂O₅ layer, where index x refers to the content of Ti. If TiN is deposited on Ta₂O₅, exposure to H₂ has the effect of reducing the TiN, thereby releasing nitrogen to form TaₓO_{y}N_{z} at the Si interface.

FIG. 8 is a schematic diagram of a cross section of stack of layers 80 showing a reaction employed in a further embodiment of the present invention in order to generate metal doped silicide. Mixing of various metals into suicides is very desirable to lower the resistivity, to prevent spiking, and to provide diffusion barriers. Stack of layers 80 is similar to stack of layers 24 of FIG. 2a) and has substrate 82 of compound S, namely silicon Si, layer 84 of compound SW and thereupon layer 86 of compound YZ with surface 88 towards gas 90 comprising compound X. Layer 84 of compound SW is of a silicide which can contain a metal. Layer 86 of compound YZ contains the desired metal M, i.e. Z=M. In this case the layer YZ consists either of a silicide MₓSi_{y}, where M stands for the desired metal and indices x, y refer to the chemical composition, i.e. Y=Si, Z=M, or simply of pure metal layer M, i.e. Y=M, Z=M. Note that in this embodiment, according to FIG. 8, layer 84 is of compound SW which is silicide and includes compound S (Si) of substrate 82.

Upon oxidation of layer YZ many of the metal particles incorporate into the layer SW thus doping this silicide with foreign metal particles in a very controllable way. This is a very useful result.

FIG. 9a) is a schematic diagram of a cross section of stack of layers 100 which is employed in still another embodiment of the present invention in order to generate nitrogen doped oxide. Stack of layers 100 is similar to stack of layers 24 of FIG. 2a) and has substrate 102, thereupon formed first layer 104 of oxide (i.e. SiO₂), and thereupon formed second layer 106 of TiN with surface 108 towards gas 110 which is capable of reducing TiN and comprises H₂. Interface 107 is between first layer 104 and second layer 106. Substrate 102 is conveniently a semiconductor, as for example Si, but other semiconductors are also useful. In this embodiment, according to FIG. 9, the compounds are X=hydrogen H, Y=titanium Ti, Z=nitrogen N, S=silicon Si and W=oxygen O.

The reaction according to the invention can comprise annealing in a gas comprising hydrogen or an oxidation process such that nitrogen atoms are released and incorporate into the first layer. During the reaction the TiN of second layer 106 is reduced releasing nitrogen which will subsequently incorporate into subjacent first layer 104 of oxide. Stack of layers 100 is shown before the chemical reaction starts. The reaction will result in very controlled doping of first layer 104 with nitrogen. The chemical reaction can be controlled to consume second layer 106 completely or partially.

FIG. 9b) is a schematic diagram of a cross section of stack of layers 100′ after partial reduction, second layer 106 of TiN of FIG. 9a) according to another embodiment of the present invention in order to generate a nitrogen doped layer. Stack of layers 100′ has substrate 102′, thereupon formed first layer 104′ of oxide (i.e. SiO₂), and thereupon formed second layer 106′ of TiN with new surface 108′. Because of the partially reduction second layer 106′ of TiN is thinner than second layer 106 of TiN of FIG. 9a). Interface 107′ between first layer 104′ and second layer 106′ now comprises nitrogen atoms which have been released by the reaction.

In the embodiments according to the invention described above the source layer is completely consumed or is partially consumed and becomes part of the adjacent layer. Furthermore, the diffusant is a majority component of the source layer. In any case there is nothing left from the source layer which is removed by etching. Thus, the adjacent layer is not damaged. The method according to the invention achieves ultrathin dielectric layers with greatly improved electrical features.

The surface layer containing the dopant according to the invention has a thickness in the range between 1 and 10 nm, preferably in the range between 2 and 6 nm.

The underlayer according to the invention has a thickness in the range between 1-15 nm, preferably in the range between 1 and 6 nm.

The resulting stack of layers according to the invention above (without) the substrate has a total thickness smaller than 20 nm, more conveniently smaller than 10 nm, and preferably smaller than 5 nm.

The structures and stacks of layers described above in FIGS. 2 and 3a) were achieved by the following process:

1. A thermal oxide was grown on a silicon wafer in oxygen and helium between 900 and 1000° C. using a horizontal diffusion furnace. The thickness was approximately 35 Angstrom Units (Å) (i.e.≈3.5 nm).

2. A silicon nitride layer was deposited on top of the oxide layer at a deposition temperature between 725° C. and 780° C. using dichlorosilane and ammonia as precursors. The thickness was approximately 60 Angstrom Units (Å) (i.e.≈6 nm).

3. The wafer was then subjected to oxidation at a temperature of 900° C. in O₂/H₂O ambient so as to completely consume the nitride layer.

A preferred method to generate structures and stacks of layers similar to those described above in FIGS. 2. and 3 according to the invention is the following process:

1. A vertical diffusion furnace a or a single wafer tool (rapid thermal processing (RTP) chamber) is used to grow the thermal oxide. The temperature range would be 700° C. to 950° C. for the vertical furnace case and 800° C. to 1150° C. for the single wafer tool.

2. The silicon nitride layer is grown in a vertical furnace using similar process condition to the deposition on top of the oxide layer at a deposition temperature between 725° C. and 780° C. using dichlorosilane and ammonia as precursors. Alternatively a single wafer rapid thermal CVD chamber can be used to deposit the silicon nitride layer. A typical process condition for the latter case is a deposition temperature of 750° C. and a pressure of 10 torr (i.e. 1330 Pa). The precursor gases can be dichlorosilane/NH₃ or silane/NH₃.

3. The oxidation step is carried out in a vertical furnace or an RTP oxidation chamber. A typical oxidation temperature is 750 to 1000° C. The oxidation ambient could be oxygen or steam with or without HCl or other Cl bearing gas.

Those of skill in the art will know that the invention is not limited by first layer 104 being of oxide. Also they know that second layer 106 can be of TaN or of another metal nitride instead of TiN.

In the foregoing detailed description of the preferred embodiment, reference is made to the accompanying drawings which form a part hereof, and in which are shown by way of illustration specific embodiments in which the invention can be practiced. These embodiments have been described in sufficient detail to enable those skilled in the art to practice the invention, and it is to be understood that other embodiments can be utilized and that chemical and mechanical changes can be made without departing from the spirit and scope of the present invention. For example, layers can be applied upon a substrate by various methods and conditions and those skilled in the art will choose the appropriate method and conditions according to the applied substance and other circumstances. The foregoing detailed description is, therefore, not to be taken in a limiting sense, and the scope of the present inventions is defined only by the appended claims.

1. A method for incorporation particles of a species from a layer of a first material to within a solid of a second material comprising the following steps:
a) forming a layer of the first material upon the solid of the second material,
b) at least partly converting the layer of the first material by a chemical reaction with a third material such that particles are released as a consequence of the chemical reaction and incorporate into the solid of the second material.

2. A method for incorporation of particles of a species from a layer of a first material to within a layer of a second material and near an interface between the second material and a third material comprising the following steps:
a) forming a layer of the second material upon a substrate of the third material,
b) forming a layer of the first material upon the layer of the second material,
c) at least partly converting the layer of the first material by a chemical reaction with a fourth material such that particles of the species are released as a consequence of the chemical reaction and incorporate into the layer of the second material.

3. The method of claim 2 wherein the first material contains particles of the species.

4. The method of claim 2 wherein the first material contains substantially no particles of the species.

5. The method of claim 2 wherein the second material includes particles of the species and the third material.

6. The method of claim 5 wherein the layer of the second material is grown near the interface between the second material and the third material by building the second material of arriving particles of the species and the third material.

7. The method of claim 2 wherein the first material is silicon nitride and the second material is silicon oxide.

8. The method of claim 7 wherein the silicon nitride layer is entirely reoxidized.

9. The method of claim 7, wherein by step c) is formed nitrogen doped silicon oxide near the silicon oxide /silicon interface with a local nitrogen concentration maximum.

10. The method of claim 2 wherein the species is nitrogen.

11. The method of claim 2 wherein the layer of the second material is of a thickness of less than 15 nm.

12. The method of claim 2 wherein the layer of the first material is of a thickness of the range from 1 nm to 10 nm.

13. The method of claim 2 wherein all steps are carried out at temperatures less than 1100° C.

14. The method of claim 2 wherein the first material is germanium oxide and the second material is silicon nitride.

15. The method of claim 2 wherein the first material comprises a metal of the group titanium, tantalum and the second material is an oxide.

16. The method of claim 2 wherein the first material is titanium nitride and the second material is tantalum oxide.

17. The method of claim 2 wherein the first material is titanium nitride and the second material is an oxide.

18. A structure having therein a silicon substrate, an oxide layer and an oxide/silicon interface between the silicon substrate and the oxide layer, the oxide layer having a surface opposite to the oxide/silicon interface, wherein at least the oxide layer contains nitrogen and the nitrogen concentration has a first maximum near the surface and has a second maximum near the oxide/silicon interface.

19. A method for regrowing a silicon oxide layer on a silicon-substrate near a silicon oxide/silicon interface comprising the following steps:
a) forming a silicon oxide layer on silicon,
b) forming a material layer upon the silicon oxide layer,
c) reacting the material layer with a gas, thereby releasing oxygen to incorporate through the silicon oxide layer and form silicon oxide near a silicon oxide/silicon interface.
